(19) United States
(12) Patent Application Publication
(10) Pub. No.: US 2026/0075902 A1
(43) Pub. Date: Mar. 12, 2026

(54) SEMICONDUCTOR DEVICE

(71) Applicant: FUJI ELECTRIC CO., LTD., Kanagawa (JP)

(72) Inventors: Misaki UCHIDA, Matsumoto-city (JP); Takashi YOSHIMURA, Matsumoto-city (JP); Shuntaro YAGUCHI, Matsumoto-city (JP)

(21) Appl. No.: 19/308,273

(22) Filed: Aug. 24, 2025

(30) Foreign Application Priority Data
Sep. 11, 2024 (JP) 2024-157801

(51) Int. Cl. H10D 62/60; H10D 8/00; H10D 12/00; H10D 62/10; H10D 62/53; H10D 84/00

(52) U.S. Cl. CPC H10D 62/60; H10D 8/422; H10D 12/481; H10D 62/105; H10D 62/53; H10D 84/161

(57) ABSTRACT

Provided is a semiconductor device which is provided in a semiconductor substrate having a first principal surface and a second principal surface and containing a bulk dopant, the semiconductor device including: in the semiconductor substrate, a first low concentration region of a first conductivity type which has a carrier concentration lower than a bulk concentration that is a concentration of the bulk dopant; and a first high concentration region of the first conductivity type which has a first carrier concentration peak at a position in contact with the first low concentration region on a side of the first principal surface and has a carrier concentration higher than the bulk concentration, in which a hydrogen concentration peak is not provided at a position overlapping with the first carrier concentration peak.

The contents of the following patent application(s) are incorporated herein by reference:
NO. 2024-157801 filed in JP on Sep. 11, 2024.

### BACKGROUND

### 1. Technical Field

The present invention relates to a semiconductor device.

### 2. Related Art

A semiconductor device in which carrier lifetime is adjusted by radiating a charged particle beam such as helium is known (see, for example, Patent Document 1).
Patent Document 1: International Publication No. WO 2020/100995

### BRIEF DESCRIPTION OF THE DRAWINGS

FIG. 1 is a cross-sectional view showing an example of a semiconductor device 100 according to one embodiment of the present invention.

FIG. 2 is a diagram showing an example of distributions of a carrier concentration, a helium chemical concentration, a hydrogen chemical concentration, and an oxygen chemical concentration taken along line A-A in FIG. 1.

FIG. 3 is a cross-sectional view showing another example of the semiconductor device 100.

FIG. 4 is a diagram showing an example of the carrier concentration distribution taken along line B-B in FIG. 3.

FIG. 5 is a cross-sectional view showing another example of the semiconductor device 100.

FIG. 6 is a diagram showing an example of the carrier concentration distribution taken along line C-C in FIG. 5.

FIG. 7 is a cross-sectional view showing another example of the semiconductor device 100.

FIG. 8A is a diagram showing an example of distributions of the carrier concentration, carrier mobility or carrier lifetime, the helium chemical concentration, a defect density, and the hydrogen chemical concentration in line D-D of FIG. 7.

FIG. 8B is a diagram showing a relationship between L (μm) and Np/L (atoms/cm⁴) in FIG. 8A.

FIG. 9 is a diagram showing an example of the carrier concentration distribution in a first high concentration region 231, a first low concentration region 211, a second high concentration region 232, and a second low concentration region 212.

FIG. 10 is a diagram showing an example of the carrier concentration distribution in the first high concentration region 231, the first low concentration region 211, the second high concentration region 232, and the second low concentration region 212.

FIG. 11 is a diagram showing an example of the carrier concentration distribution in the first high concentration region 231, the first low concentration region 211, the second high concentration region 232, and the second low concentration region 212.

FIG. 12 is a diagram for explaining a more specific embodiment of the semiconductor device 100.

FIG. 13 is an enlarged view of a region A in FIG. 12.

FIG. 14 is a view showing an example of a cross section e-e in FIG. 13.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

As used herein, one side in a direction parallel to a depth direction of a semiconductor substrate is referred to as an “upper” side and another side is referred to as a “lower” side. One surface of two principal surfaces of a substrate, a layer, or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. It should be noted that a +Z axis direction and a −Z axis direction are directions opposite to each other. When a Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor which supplies electrons. A hydrogen-related donor may be a donor which is a combination of at least a vacancy (V) and hydrogen (H). Alternatively, interstitial Si—H which is a combination of interstitial silicon (Si-i) in a silicon semiconductor and hydrogen, and CiOi-H which is a combination of interstitial carbon (Ci), interstitial oxygen (Oi), and hydrogen also function as the donor which supplies electrons. In the present specification, the VOH defect, the CiOi-H or the interstitial Si—H may be referred to herein as the hydrogen-related donor.

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of the present example is an element other than hydrogen. A dopant of the bulk donor is, for example, phosphorous, antimony, arsenic, selenium, or sulfur, but is not limited to these. The bulk donor of the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any of a Czochralski method (CZ method), a magnetic-field applied Czochralski method (MCZ method), and a float zone method (FZ method). The ingot of the present example is manufactured by the MCZ method. A concentration of oxygen contained in the substrate manufactured by the MCZ method is 1×10¹⁷ to 7×10¹⁷/cm³. A concentration of oxygen contained in the substrate manufactured by the FZ method is 1×10¹⁵ to 5×10¹⁶/cm³. When the concentration of oxygen is high, the hydrogen-related donor tends to be easily generated. A bulk donor concentration may use a chemical concentration of the bulk donors distributed throughout the semiconductor substrate, or may be a value between 90% and 100% of the chemical concentration. In addition, as the semiconductor substrate, a non-doped substrate not containing a dopant such as phosphorous may be used. In that case, a bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Note that each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

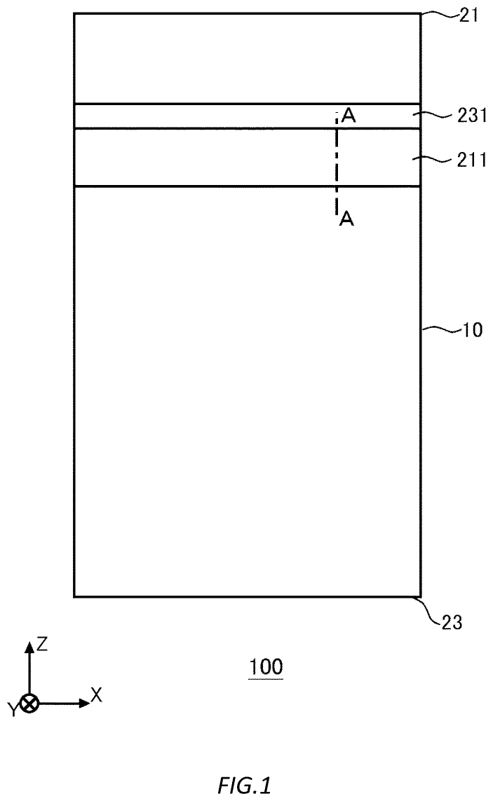

FIG. 1 is a cross-sectional view showing an example of a semiconductor device 100 according to one embodiment of the present invention. The semiconductor device 100 is provided in a semiconductor substrate 10 which has a first principal surface and a second principal surface and contains a bulk dopant. The semiconductor substrate 10 may be a silicon substrate, a silicon carbide substrate, or a substrate formed of another semiconductor material. The first principal surface and the second principal surface are two surfaces having a largest area among surfaces of the semiconductor substrate 10. The first principal surface and the second principal surface are surfaces opposite to each other. In the example of FIG. 1, an upper surface 21 of the semiconductor substrate 10 is the first principal surface, and a lower surface 23 is the second principal surface. However, the upper surface 21 may be the second principal surface, and the lower surface 23 may be the first principal surface.

In the present specification, two axes parallel to the upper surface 21 of the semiconductor substrate 10 are defined as an X axis and a Y axis, and an axis perpendicular to the upper surface 21 is defined as a Z axis. The X axis, the Y axis, and the Z axis are orthogonal to each other. A direction parallel to the Z axis may be referred to as a depth direction.

The bulk dopant is a dopant of the N type or the P type distributed throughout the semiconductor substrate 10. The bulk dopant may be a dopant substantially uniformly contained in an ingot during the manufacture of the ingot from which the semiconductor substrate 10 is made. The bulk dopant in the present specification is, for example, a bulk donor such as phosphorous, antimony, arsenic, selenium, or sulfur, but is not limited to these. The semiconductor substrate 10 may be a substrate of the N type.

The semiconductor device 100 includes a first low concentration region 211 and a first high concentration region 231 in the semiconductor substrate 10. The first low concentration region 211 is a region of a first conductivity type having a carrier concentration lower than a bulk concentration which is a concentration of the bulk dopant. In the present specification, the N type is the first conductivity type, and the P type is a second conductivity type. As the concentration of the bulk dopant, an average value of the concentration of the bulk dopant in the entire semiconductor substrate 10 may be used. When an element of a same type as the bulk dopant is locally implanted in the semiconductor substrate 10, an average value of the concentration of the bulk dopant in a region other than the locally implanted region may be set as the concentration of the bulk dopant. For example, when a concentration of the element of the same type as the bulk dopant shows a peak, the average value of the bulk dopant may be calculated excluding the peak portion. In another example, a minimum value of the concentration of the bulk dopant in the semiconductor substrate 10 may be used as the concentration of the bulk dopant.

The first low concentration region 211 can be formed by irradiating an inside of the semiconductor substrate 10 with charged particles such as helium ions. The charged particles such as helium ions cause disorder of a crystal structure such as a lattice defect inside the semiconductor substrate 10, and carrier mobility and carrier lifetime are reduced. With this configuration, the carrier concentration measured by the SRP method or the like decreases.

The first high concentration region 231 is a region of the N type provided at a position in contact with the first low concentration region 211 on an upper surface 21 side and having a carrier concentration higher than the bulk concentration. The first high concentration region 231 and the first low concentration region 211 may be provided on the upper surface 21 side or a lower surface 23 side in the semiconductor substrate 10.

The first high concentration region 231 may include the hydrogen-related donor. As described above, the hydrogen-related donor is any one or more of the VOH defect, the CiOi-H, or the interstitial Si—H. Irradiation of charged particles in a vicinity of a region where hydrogen is present or passage of charged particles through the region where hydrogen is present can cause the above-described disorder of the crystal structure to generate the hydrogen-related donor.

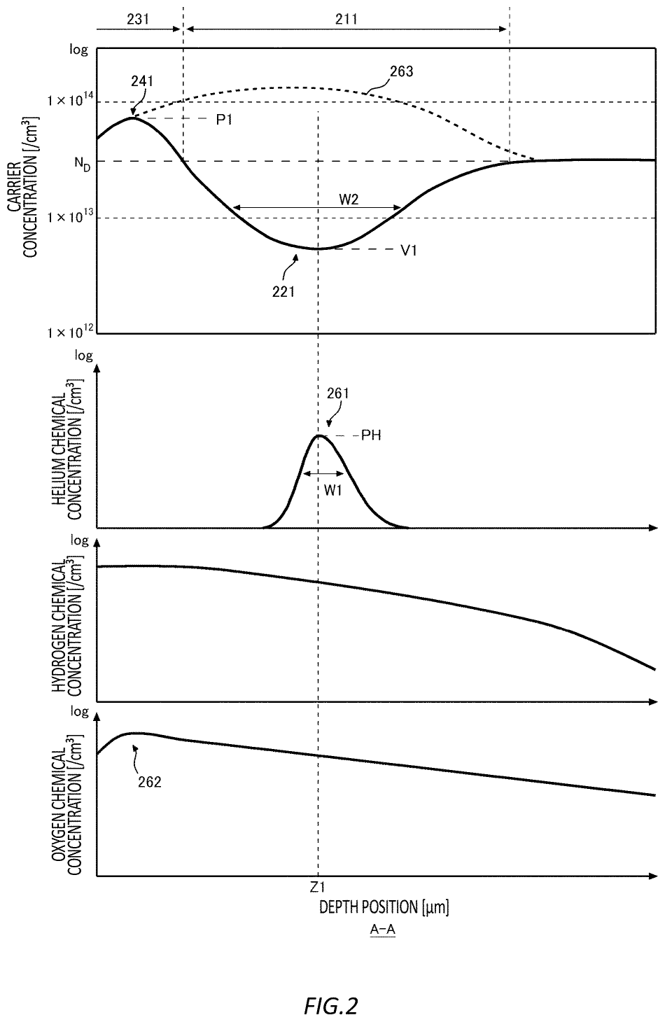

FIG. 2 is a diagram showing an example of distributions of the carrier concentration, a helium chemical concentration, a hydrogen chemical concentration, and an oxygen chemical concentration taken along line A-A of FIG. 1. Line A-A is a line which passes through a part of the first high concentration region 231 and the first low concentration region 211 and is parallel to the Z axis. In each example in the present specification, helium ions are used as an example of the charged particles, but the charged particles may be other charged particles. In this case, the helium chemical concentration herein can be replaced with a concentration of the other charged particles.

As described above, the first low concentration region 211 is a region having a carrier concentration lower than a bulk concentration N_{D}. The first low concentration region 211 has a first valley portion 221 in which the carrier concentration shows a local minimum value V1. The local minimum value V1 may be 90% or less, 70% or less, 50% or less, or 10% or less of the bulk concentration N_{D}. A valley portion of the concentration may have a skirt portion where the carrier concentration monotonically increases, from a position where the carrier concentration shows a local minimum value, toward the upper surface 21 to a predetermined concentration (for example, bulk concentration), and a skirt portion where the carrier concentration monotonically increases, from the position, toward the lower surface 23 to the predetermined concentration (for example, bulk concentration). In the present specification, a monotonic increase in concentration in a predetermined direction means that the concentration increases or is maintained as it moves in the predetermined direction, and there is no region where the concentration decreases. In addition, a monotonic decrease in concentration in the predetermined direction means that the concentration decreases or is maintained as it moves in the predetermined direction, and there is no region where the concentration increases.

As described above, the first high concentration region 231 is a region having a carrier concentration higher than the bulk concentration N_{D}. The first high concentration region 231 has a first carrier concentration peak 241 at a position in contact with the first low concentration region 211 on the upper surface 21 side. At the first carrier concentration peak 241, the carrier concentration shows a local maximum value P1. The local maximum value P1 may be 1.1 times or more, 1.5 times or more, 2 times or more, or 10 times or more the bulk concentration N_{D}. A peak of the concentration may have a skirt portion where the carrier concentration monotonically decreases, from a position where the carrier concentration shows a local maximum value, toward the upper surface 21 to a predetermined concentration (for example, bulk concentration), and a skirt portion where the carrier concentration monotonically decreases, from the position, toward the lower surface 23 to the predetermined concentration (for example, bulk concentration).

When the first carrier concentration peak 241 is in contact with the first low concentration region 211, this may mean that a skirt portion of the first carrier concentration peak 241 and a skirt portion of the first valley portion 221 are continuous. In addition, when the first carrier concentration peak 241 is in contact with the first low concentration region 211, this may mean that there is no region where the carrier concentration is constant between the first carrier concentration peak 241 and the first low concentration region 211. In addition, when the first carrier concentration peak 241 is in contact with the first low concentration region 211, this may mean that the carrier concentration continues to increase from a position where the carrier concentration shows the local minimum value V1 to a position where the carrier concentration shows the local maximum value P1.

The first low concentration region 211 of the present example has a helium concentration peak 261 at which the helium chemical concentration shows a local maximum value PH. In the present example, helium ions are implanted from the lower surface 23 of the semiconductor substrate 10 to a position Z1 included in the first low concentration region 211. The helium ions may be implanted from the upper surface 21 of the semiconductor substrate 10. In a vicinity of the helium ion implantation position Z1, many disorders of the crystal structure such as crystal defects occur. Therefore, the carrier concentration decreases, and the first low concentration region 211 is formed.

In the semiconductor substrate 10 of the present example, the hydrogen chemical concentration monotonically decreases as a distance from the upper surface 21 increases. For example, by annealing the semiconductor substrate 10 in a hydrogen-containing atmosphere, hydrogen diffuses from the upper surface 21 of the semiconductor substrate 10 toward the inside of the semiconductor substrate 10. Alternatively, hydrogen contained in an interlayer dielectric film or the like formed on the upper surface 21 of the semiconductor substrate 10 diffuses from the upper surface 21 toward the inside of the semiconductor substrate 10. In this case, as shown in FIG. 2, the hydrogen chemical concentration decreases as the distance from the upper surface 21 increases.

The first high concentration region 231 includes a hydrogen-related donor formed by the hydrogen present in the semiconductor substrate 10. The hydrogen-related donor is formed by the disorder of the crystal structure caused by implantation of charged particles such as helium ions and hydrogen. For example, as indicated by a broken line 263, the hydrogen-related donors are also formed in the first low concentration region 211 in the vicinity of the helium ion implantation position Z1. However, since a density of crystal defects or the like is high in the first low concentration region 211, the carrier concentration is lower than the bulk concentration N_{D}.

On the other hand, in the first high concentration region 231 away from the helium ion implantation position Z1, the density of crystal defects or the like is relatively low and the hydrogen concentration is relatively high, so that a concentration of the hydrogen-related donor is relatively high as compared with that of remaining crystal defects, and the carrier concentration is higher than the bulk concentration N_{D}. In the present example, the first carrier concentration peak 241 is a peak of the hydrogen-related donor. When the carrier concentration shows a peak in a region where hydrogen is present and a peak of a dopant of the N type other than hydrogen is not present, the peak of the carrier concentration may be regarded as the peak of the hydrogen-related donor.

In the present example, the first carrier concentration peak 241 is formed without implanting hydrogen ions into the first high concentration region 231. Therefore, a hydrogen concentration peak is not provided at a position overlapping with the first carrier concentration peak 241. In the present specification, when concentration peaks do not overlap with each other, this may mean that a position of a local maximum of one peak is not included in a depth range of a full width at half maximum of another peak. Alternatively, this may mean that ranges of the full widths at half maximum of two peaks do not even partially overlap with each other. In the semiconductor substrate 10, the hydrogen concentration peak in the depth direction may not be provided at any position. In the semiconductor substrate 10 of another example, the hydrogen concentration peak may be provided at a position not overlapping with the first carrier concentration peak 241.

In the present example, since it is not necessary to implant hydrogen ions into the first high concentration region 231, both the first low concentration region 211 and the first high concentration region 231 can be formed by a simple manufacturing step. The first low concentration region 211 can be used as, for example, a lifetime adjustment region in which the carrier lifetime is reduced in the semiconductor device 100. For example, when the semiconductor device 100 includes a transistor such as an insulated gate bipolar transistor (IGBT) and a diode, a lifetime adjustment region in which the carrier lifetime is reduced may be formed in order to shorten a reverse recovery time of the diode. The lifetime adjustment region is also formed in a transistor adjacent to the diode.

The first high concentration region 231 can be used as an accumulation region arranged adjacent to the lifetime adjustment region. For example, in a transistor such as an IGBT, an accumulation region of an N+ type may be formed below a base layer of the P type in order to promote accumulation of carriers and reduce on-resistance. In this case, the lifetime adjustment region and the accumulation region can be formed by a simple manufacturing step.

However, the use of the first low concentration region 211 and the first high concentration region 231 is not limited to a combination of the lifetime adjustment region and the accumulation region. The first low concentration region 211 and the first high concentration region 231 can be used as long as a region where the carrier concentration is lower than the bulk concentration N_{D} and a region where the carrier concentration is higher than the bulk concentration N_{D} are arranged adjacent to each other.

The oxygen chemical concentration may monotonically decrease away from the upper surface 21. However, by annealing the semiconductor substrate 10, oxygen in a vicinity of the upper surface 21 of the semiconductor substrate 10 may be released to an outside of the semiconductor substrate 10. The oxygen chemical concentration may have an oxygen concentration peak 262 in the vicinity of the upper surface 21 of the semiconductor substrate 10 and monotonically decrease at a position deeper than the oxygen concentration peak 262. The oxygen concentration peak 262 may be arranged on the upper surface 21 side with respect to the first low concentration region 211. The oxygen concentration peak 262 may be arranged in the first high concentration region 231. The oxygen concentration peak 262 may be arranged at a position overlapping with the first carrier concentration peak 241. Formation of the hydrogen-related donor is promoted as the oxygen chemical concentration increases, and the first carrier concentration peak 241 is easily formed.

A width of the helium concentration peak 261 in the depth direction is W1, and a width of the first low concentration region 211 in the depth direction is W2. The width W1 may be a width of a region where the helium chemical concentration is equal to or more than a half of the local maximum value PH at the helium concentration peak 261 (that is, a full width at half maximum). In this case, the width W2 may be a width of a region where the carrier concentration is twice or more the local minimum value V1 in the first low concentration region 211. Alternatively, the width W2 may be a width of a region where the carrier concentration is a half or less of the bulk concentration N_{D} in the first low concentration region 211. The width W1 may be a width of a region where the helium chemical concentration is 10% or more of the local maximum value PH in the helium concentration peak 261. In this case, the width W2 may be a width of a region where the carrier concentration is 9 times or less the local minimum value V1 in the first low concentration region 211 or a width of a region where the carrier concentration is 90% or less of the bulk concentration N_{D} in the first low concentration region 211.

The width W1 may be smaller than the width W2. The width W1 may be equal to or less than a half or ¼ of the width W2. By reducing the width W1, a position of the region where the first low concentration region 211 is formed can be accurately controlled. In another example, the width W1 may be greater than the width W2. The width W1 varies depending on a system of a device for accelerating helium ions or the like. For example, the width W1 can be made greater than the width W2 by using a cyclotron type acceleration device. In this case, the crystal defects or the like can be formed in a wide range.

A difference (P1−N_{D}) between the bulk concentration N_{D} and the local maximum value P1 of the first carrier concentration peak 241 may be smaller than a difference (N_{D}−V1) between the bulk concentration N_{D} and the local minimum value V1 of the first valley portion 221. The difference (P1−N_{D}) may be equal to or less than a half or ¼ of the difference (N_{D}−V1). In another example, the difference (P1−N_{D}) may be greater than the difference (N_{D}−V1).

In the depth direction, a width of the first high concentration region 231 may be smaller than a width of the first low concentration region 211. The width of the first high concentration region 231 may be equal to or less than a half or ¼ of the width of the first low concentration region 211.

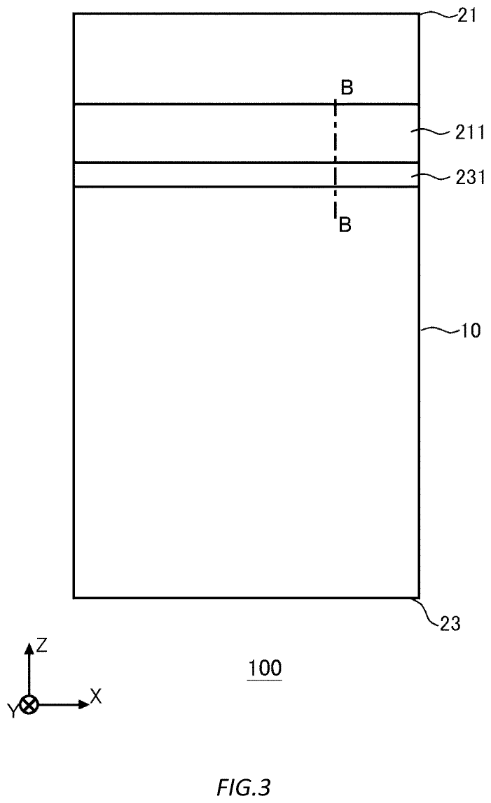

FIG. 3 is a cross-sectional view showing another example of the semiconductor device 100. In the present example, the first high concentration region 231 is provided in contact with the first low concentration region 211 on the lower surface 23 side of the semiconductor substrate 10. Other structures are similar to those of the examples described in FIGS. 1 and 2. In the present example, the lower surface 23 is the first principal surface, and the upper surface 21 is the second principal surface. The first high concentration region 231 and the first low concentration region 211 are provided on the upper surface 21 side of the semiconductor substrate 10.

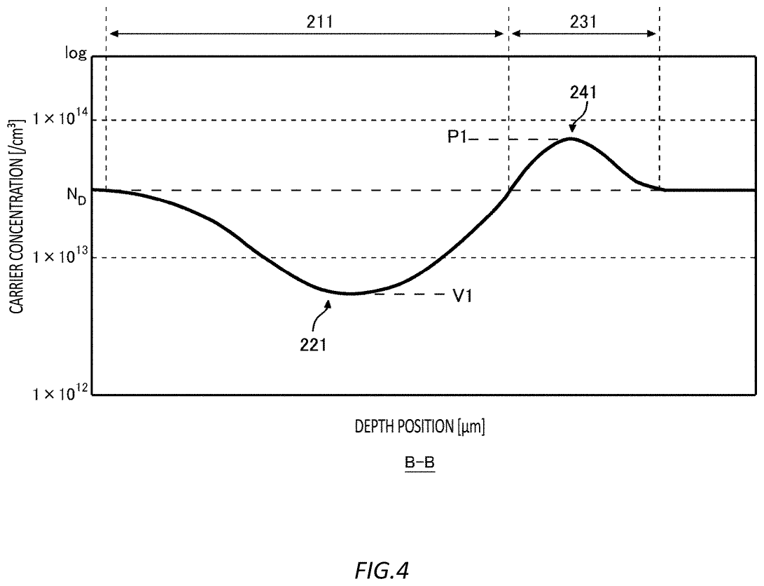

FIG. 4 is a diagram showing an example of the carrier concentration distribution taken along line B-B in FIG. 3. Line B-B is a line which passes through the first high concentration region 231 and the first low concentration region 211 and is parallel to the Z axis.

The carrier concentration distribution in the present example may have a shape in which the carrier concentration in the example shown in FIG. 2 is reversed in the depth direction. For example, the first carrier concentration peak 241 is in contact with the first low concentration region 211 on the lower surface 23 side.

Each distribution of the helium chemical concentration, the hydrogen chemical concentration, and the oxygen chemical concentration may be similar to or different from the example of FIG. 2. Helium ions may be implanted from the upper surface 21 or from the lower surface 23.

In the present example, a hydrogen chemical concentration of the first high concentration region 231 may be higher than a hydrogen chemical concentration of the first low concentration region 211. For example, by implanting and diffusing hydrogen ions to the lower surface 23 side with respect to the first high concentration region 231, the hydrogen chemical concentration of the first high concentration region 231 becomes higher than the hydrogen chemical concentration of the first low concentration region 211. The semiconductor substrate 10 may have a concentration peak of the hydrogen chemical concentration on the lower surface 23 side with respect to the first high concentration region 231. With the configuration of the present example, for example, expansion of a space charge region or a depletion layer of an IGBT or a diode can be suppressed, and switching characteristics can be improved.

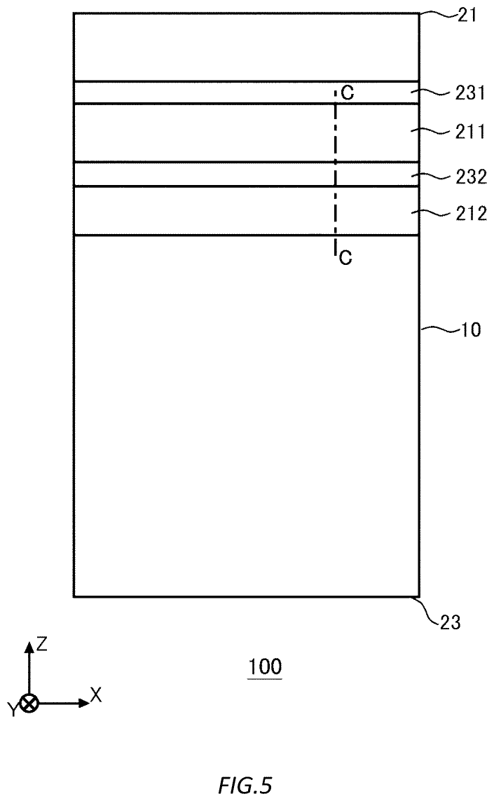

FIG. 5 is a cross-sectional view showing another example of the semiconductor device 100. The semiconductor device 100 of the present example further includes a second high concentration region 232 as compared with the example described in FIGS. 1 and 2. The semiconductor device 100 may further include the second low concentration region 212. The second low concentration region 212 may not be provided in the semiconductor device 100. Other structures are similar to those of the examples described in FIGS. 1 and 2.

The second high concentration region 232 is a region of the N type provided at a position in contact with the first low concentration region 211 on the lower surface 23 side and having a carrier concentration higher than the bulk concentration N_{D}. The second high concentration region 232 may include the hydrogen-related donor.

The second low concentration region 212 is a region of the N type provided at a position in contact with the second high concentration region 232 on the lower surface 23 side. In the second low concentration region 212, the carrier concentration may be lower than the bulk concentration N_{D}.

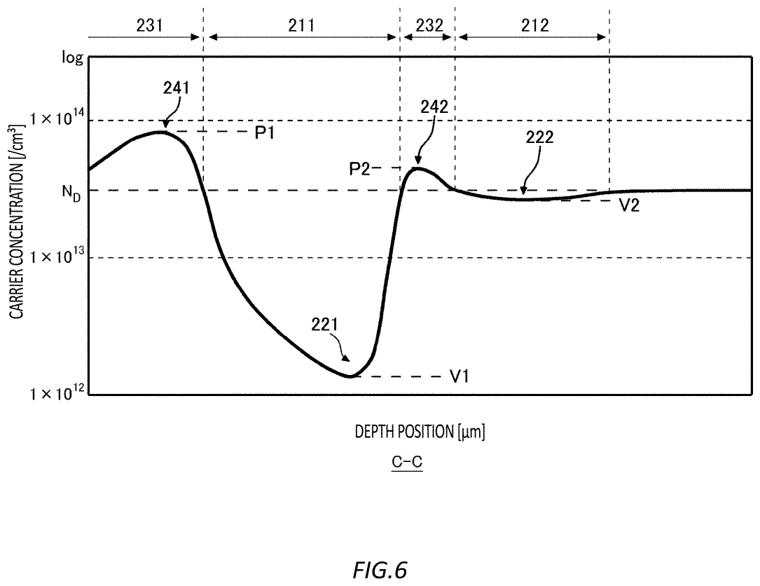

FIG. 6 is a diagram showing an example of the carrier concentration distribution taken along line C-C in FIG. 5. Line C-C is a line which passes through a part of the first high concentration region 231, the first low concentration region 211, the second high concentration region 232, and the second low concentration region 212 and is parallel to the Z axis. Each distribution of the helium chemical concentration, the hydrogen chemical concentration, and the oxygen chemical concentration may be similar to or different from the example of FIG. 2.

The carrier concentration distribution in the first low concentration region 211 and the first high concentration region 231 is similar to that in the example of FIG. 2. As described above, the second high concentration region 232 is a region where the carrier concentration is higher than the bulk concentration N_{D}. The second high concentration region 232 has a second carrier concentration peak 242 at a position in contact with the first low concentration region 211 on the lower surface 23 side. At the second carrier concentration peak 242, the carrier concentration shows a local maximum value P2. The local maximum value P2 may be 1.1 times or more, 1.5 times or more, 2 times or more, or 10 times or more the bulk concentration N_{D}.

When the second carrier concentration peak 242 is in contact with the first low concentration region 211, this may mean that a skirt portion of the second carrier concentration peak 242 and a skirt portion of the first valley portion 221 are continuous. In addition, when the second carrier concentration peak 242 is in contact with the first low concentration region 211, this may mean that there is no region where the carrier concentration is constant between the second carrier concentration peak 242 and the first low concentration region 211. In addition, when the second carrier concentration peak 242 is in contact with the first low concentration region 211, this may mean that the carrier concentration continues to increase from a position where the carrier concentration indicates the local minimum value V1 to a position where the carrier concentration indicates the local maximum value P2.

Also in the present example, similarly to the example of FIG. 2, the first low concentration region 211 has the helium concentration peak 261. Helium ions may be implanted from the lower surface 23 or from the upper surface 21.

In the semiconductor substrate 10 of the present example, the hydrogen chemical concentration may monotonically decrease as the distance from the upper surface 21 increases. However, in the present example, hydrogen is also present in the second high concentration region 232 to such an extent that the second carrier concentration peak 242 can be formed. The second carrier concentration peak 242 may be a peak of the hydrogen-related donor. The second carrier concentration peak 242 may be formed by the hydrogen present in the semiconductor substrate 10 and the disorder of the crystal structure caused by implantation of charged particles such as helium ions. The local maximum value P2 of the second carrier concentration peak 242 may be smaller than the local maximum value P1 of the first carrier concentration peak 241. The hydrogen chemical concentration at the second carrier concentration peak 242 may be lower than the hydrogen chemical concentration at the first carrier concentration peak 241.

In another example, the hydrogen chemical concentration at the second carrier concentration peak 242 may be higher than the hydrogen chemical concentration at the first carrier concentration peak 241. For example, by implanting and diffusing hydrogen ions on the lower surface 23 side with respect to the second carrier concentration peak 242, the hydrogen chemical concentration at the second carrier concentration peak 242 becomes higher than the hydrogen chemical concentration at the first carrier concentration peak 241. In this case, the local maximum value P2 of the second carrier concentration peak 242 may be higher than the local maximum value P1 of the first carrier concentration peak 241. In addition, the concentration peak of the hydrogen chemical concentration may be present on the lower surface 23 side with respect to the second carrier concentration peak 242.

In the present example, the first carrier concentration peak 241 and the second carrier concentration peak 242 are formed without implanting hydrogen ions into any of the first high concentration region 231 or the second high concentration region 232. The hydrogen concentration peak may not be provided at a position overlapping with the second carrier concentration peak 242. Therefore, the first low concentration region 211, the first high concentration region 231, and the second high concentration region 232 can be formed by a simple manufacturing step. The second high concentration region 232 may be used as a part of a drift region in an IGBT or the like, for example.

A difference (P2−−N_{D}) between the bulk concentration N_{D} and the local maximum value P2 of the second carrier concentration peak 242 may be smaller than a difference (N_{D}−V1) between the bulk concentration N_{D} and the local minimum value V1 of the first valley portion 221. The difference (P2−N_{D}) may be equal to or less than a half or ¼ of the difference (N_{D}−V1). In another example, the difference (P2−N_{D}) may be greater than the difference (N_{D}−V1).

In the depth direction, a width of the second high concentration region 232 may be smaller than the width of the first low concentration region 211. The width of the second high concentration region 232 may be equal to or less than a half or ¼ of the width of the first low concentration region 211.

The second low concentration region 212 has a second valley portion 222 of the carrier concentration at a position in contact with the second high concentration region 232 on the lower surface 23 side. The second valley portion 222 shows a local minimum value V2 of the carrier concentration. The local minimum value V2 may be lower than the bulk concentration N_{D} or may be the same as the bulk concentration N_{D}. The entire second low concentration region 212 may have a carrier concentration lower than the bulk concentration N_{D}. The second low concentration region 212 may or may not have the hydrogen-related donor. For example, in the second low concentration region 212, a number of at least one hydrogen-related donor is relatively small and a number of at least one remaining crystal defect or the like is relatively large, so that the carrier concentration is relatively low. A region having a same carrier concentration as the bulk concentration N_{D} may be provided on the lower surface 23 side with respect to the second low concentration region 212. With the configuration of the present example, for example, the expansion of the depletion layer is suppressed in the second high concentration region 232, and subsequently the expansion of the depletion layer is alleviated by the second low concentration region 212, whereby occurrence of avalanche breakdown can be suppressed.

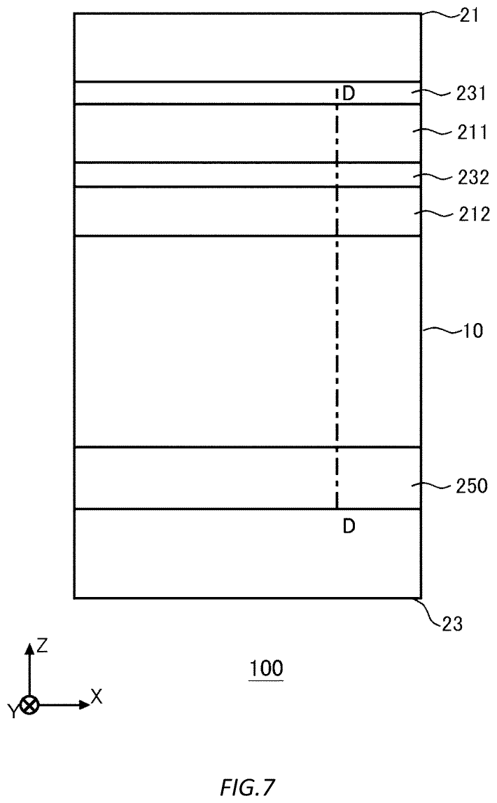

FIG. 7 is a cross-sectional view showing another example of the semiconductor device 100. The semiconductor device 100 of the present example further includes a hydrogen peak region 250, as compared with any example described in FIGS. 1 to 6. Other structures are similar to those of any of the examples described in FIGS. 1 to 6. FIG. 7 shows an example in which the hydrogen peak region 250 is added to the example shown in FIG. 5.

The hydrogen peak region 250 is a region including one or more hydrogen concentration peaks in the depth direction. The hydrogen peak region 250 is arranged on the lower surface 23 side with respect to the first low concentration region 211. The hydrogen peak region 250 may be arranged on the lower surface 23 side with respect to the second high concentration region 232. The hydrogen peak region 250 may be arranged on the lower surface 23 side with respect to the second low concentration region 212. The hydrogen peak region 250 may be arranged in a region (that is, a region on the lower surface 23 side with respect to a center in the depth direction) on the lower surface 23 side in the semiconductor substrate 10.

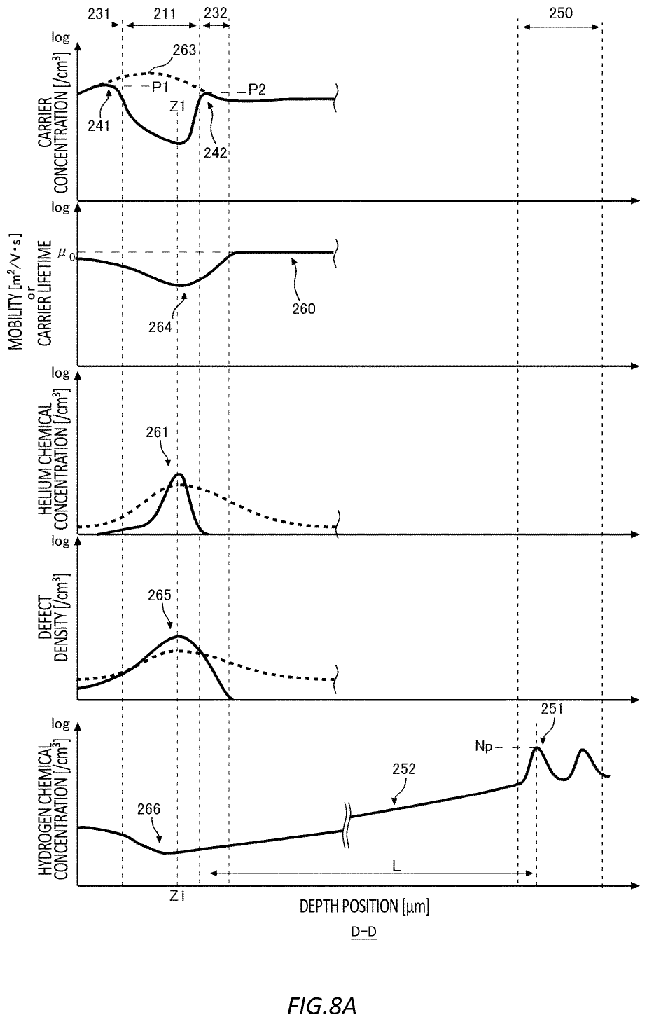

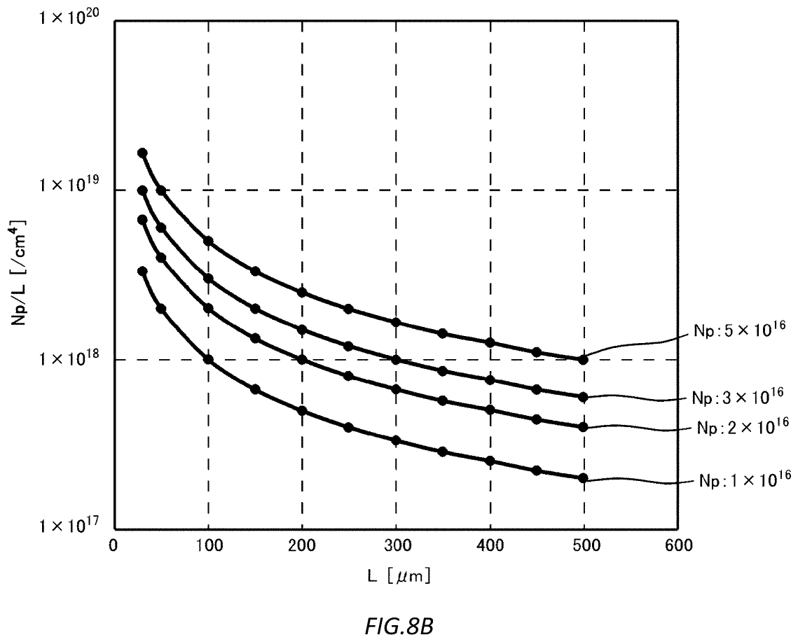

FIG. 8A is a diagram showing an example of distributions of the carrier concentration, the carrier mobility or the carrier lifetime, the helium chemical concentration, a defect density, and the hydrogen chemical concentration in line D-D of FIG. 7. Line D-D is a line which passes through regions from the first high concentration region 231 to the hydrogen peak region 250 and is parallel to the Z axis. The distribution of the oxygen chemical concentration may be similar to or different from the example of FIG. 2.

As described above, hydrogen peak region 250 has one or more hydrogen concentration peaks 251. In the hydrogen concentration peaks 251, the hydrogen chemical concentration shows a local maximum value Np. Each of the hydrogen concentration peaks 251 is arranged on the lower surface 23 side with respect to the second carrier concentration peak 242.

A distance L in the depth direction of the semiconductor substrate 10 between the hydrogen concentration peak 251 and the second carrier concentration peak 242 may be equal to or more than ¼ of a thickness in the depth direction of the semiconductor substrate 10. The distance L may be equal to or more than a half or ¾ of the thickness of the semiconductor substrate 10. Even when the distance L is large, hydrogen implanted at a position of the hydrogen concentration peak 251 can be diffused to a position of the second carrier concentration peak 242 by increasing a dose amount of hydrogen ions, increasing an annealing temperature of the semiconductor substrate 10, or increasing an annealing time. When a plurality of hydrogen concentration peaks 251 are provided, the distance L may be a distance between the hydrogen concentration peak 251 closest to the second carrier concentration peak 242 and the second carrier concentration peak 242. The distance L may be a distance between the hydrogen concentration peak 251 having a highest hydrogen chemical concentration and the second carrier concentration peak 242.

A hydrogen concentration of the hydrogen concentration peak 251 may be 1×10¹⁶/cm³ or more. When a plurality of hydrogen concentration peaks 251 are provided, the hydrogen concentration of at least one of the hydrogen concentration peaks 251 may be 1×10¹⁶/cm³ or more, the hydrogen concentration of the hydrogen concentration peak 251 closest to the second carrier concentration peak 242 may be 1×10¹⁶/cm³ or more, and the hydrogen concentrations of all the hydrogen concentration peaks 251 may be 1×10¹⁶/cm³ or more.

By annealing the semiconductor substrate 10, hydrogen diffuses from the hydrogen concentration peak 251 toward the upper surface 21. A flat hydrogen concentration portion 252 having a flat hydrogen concentration in the depth direction of the semiconductor substrate 10 may be provided between the first carrier concentration peak 241 and the hydrogen concentration peak 251. The flat hydrogen concentration means that the hydrogen concentration has neither a local maximum value nor a local minimum value. In the flat hydrogen concentration portion 252, the hydrogen chemical concentration may monotonically decrease from the hydrogen concentration peak 251 toward the upper surface 21. When the second high concentration region 232 is provided, the flat hydrogen concentration portion 252 is provided between the hydrogen concentration peak 251 and the second carrier concentration peak 242.

The flat hydrogen concentration portion 252 may be provided over a half or more of a region between the hydrogen peak region 250 and the first carrier concentration peak 241, or may be provided over ¾ or more of the region. The distribution of the hydrogen chemical concentration may have a fourth valley portion 266 in which the hydrogen chemical concentration shows a local minimum value between the first carrier concentration peak 241 and the hydrogen peak region 250. The fourth valley portion 266 may be arranged in the first low concentration region 211. The fourth valley portion 266 may be formed by hydrogen diffusing from the upper surface 21 toward the lower surface 23 of the semiconductor substrate 10 and hydrogen diffusing from the hydrogen peak region 250 toward the upper surface 21. Since the fourth valley portion 266 is provided, the first high concentration region 231 and the second high concentration region 232 can be easily formed so as to sandwich the first low concentration region 211.

The carrier mobility shows a local minimum value in the vicinity of the helium ion implantation position Z1. The same applies to the carrier lifetime. The semiconductor substrate 10 may have a third valley portion 264 in which the carrier mobility and the carrier lifetime shows local minimum values. The third valley portion 264 may overlap with the first low concentration region 211.

The semiconductor substrate 10 may have a constant lifetime portion 260 between the second carrier concentration peak 242 and the hydrogen concentration peak 251. The constant lifetime portion 260 is a region where the carrier lifetime is constant in the depth direction. The constant carrier lifetime may be a region where a maximum value of the carrier lifetime is 1.1 times or less a minimum value. The constant lifetime portion 260 may be provided in a range of a half or more or a range of ¾ or more between the second carrier concentration peak 242 and the hydrogen concentration peak 251. The constant lifetime portion 260 may be provided in an entire region from the second low concentration region 212 to the hydrogen concentration peak 251. The constant lifetime portion 260 may be a region where the carrier mobility is mobility (for example, mobility μ₀ in silicon) in a material of the semiconductor substrate 10. By implanting helium ions from the upper surface 21 side, the constant lifetime portion 260 can be easily formed in a region through which helium ions do not pass.

Similarly to the example of FIG. 2, the helium concentration peak 261 may be provided in the first low concentration region 211. The helium concentration peak 261 may have a smaller width in the depth direction than the first low concentration region 211 as indicated by a solid line in FIG. 8A, and may have a larger width in the depth direction than the first low concentration region 211 as indicated by a broken line.

Between the concentration P1 of the first carrier concentration peak 241 and the concentration P2 of the second carrier concentration peak 242, one closer to the helium concentration peak 261 may be lower than another. In the example of FIG. 8A, the second carrier concentration peak 242 is arranged closer to the helium concentration peak 261 than the first carrier concentration peak 241. Since a region closer to the helium concentration peak 261 has a higher defect density, the carrier concentration tends to be low. In the example of FIG. 8A, the concentration P2 is lower than the concentration P1. The concentration P1 may be 1.2 times or more, 1.5 times or more, or 2 times or more the concentration P2.

A defect density distribution has a defect density peak 265 in the depth direction. The defect density peak 265 overlaps with the helium concentration peak 261. The defect density peak 265 of the present example overlaps with the first high concentration region 231 and the first low concentration region 211. The defect density peak 265 may overlap with the second high concentration region 232 or the second low concentration region 212 (see FIG. 6).

FIG. 8B is a diagram showing a relationship between L (μm) and Np/L (atoms/cm⁴) in FIG. 8A. For example, Np is defined as a hydrogen peak concentration of the hydrogen concentration peak 251 closest to the upper surface 21. The hydrogen peak concentration is, as an example, 1×10¹⁶ (atoms/cm³) or more and 5×10¹⁶ (atoms/cm³) or less, but is not limited thereto. For example, the hydrogen peak concentration may be 1×10¹⁵ (atoms/cm³) or more and 1×10¹⁷ (atoms/cm³) or less. Np/L may be 1×10¹⁷ (atoms/cm⁴) or more and 2×10¹⁹ (atoms/cm⁴) or less. In this case, for example, the expansion of the depletion layer is suppressed in the second high concentration region 232, and subsequently the expansion of the depletion layer is alleviated by the second low concentration region 212, whereby the occurrence of avalanche breakdown can be suppressed.

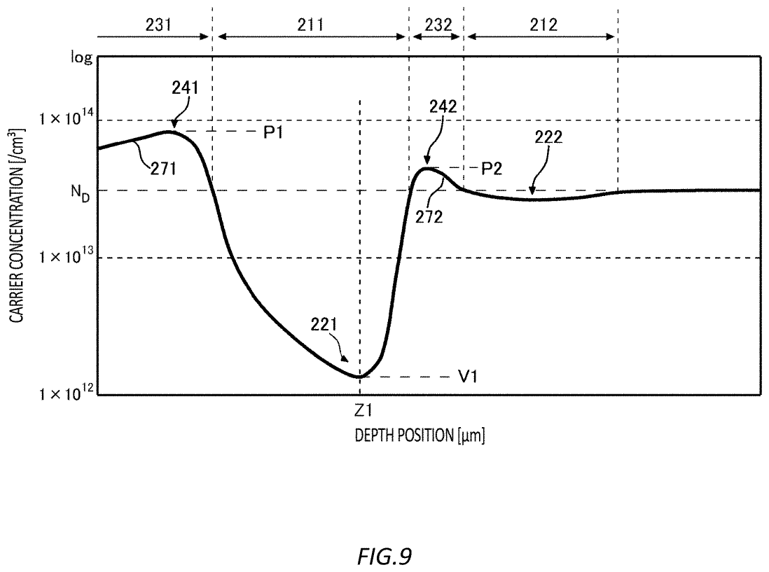

FIG. 9 is a diagram showing an example of the carrier concentration distribution in the first high concentration region 231, the first low concentration region 211, the second high concentration region 232, and the second low concentration region 212. The second low concentration region 212 may not be provided.

Between the first carrier concentration peak 241 and the second carrier concentration peak 242, one closer to any principal surface of the upper surface 21 or the lower surface 23 may have a concentration higher than that of another. In the present example, both the first carrier concentration peak 241 and the second carrier concentration peak 242 are arranged on the upper surface 21 side of the semiconductor substrate 10, and the first carrier concentration peak 241 is arranged on the upper surface 21 side with respect to the second carrier concentration peak 242. That is, the first carrier concentration peak 241 is arranged closer to the principal surface than the second carrier concentration peak 242. In the present example, the local maximum value P1 at the first carrier concentration peak 241 may be greater than the local maximum value P2 at the second carrier concentration peak 242. For example, by providing the distribution of the hydrogen chemical concentration similar to the example described in FIG. 2, the hydrogen chemical concentration in the first high concentration region 231 can be made higher than the hydrogen chemical concentration in the second high concentration region 232, and the local maximum value P1 can be made greater than the local maximum value P2. The concentration P1 may be 1.2 times or more, 1.5 times or more, or 2 times or more the concentration P2.

As described in FIG. 8A, the helium concentration peak 261 may be arranged at the implantation position Z1 of the first low concentration region 211. The first carrier concentration peak 241 and the second carrier concentration peak 242 each have an outer skirt portion on an opposite side of the helium concentration peak 261. In the example of FIG. 9, the first carrier concentration peak 241 has an outer skirt portion 271, and the second carrier concentration peak 242 has an outer skirt portion 272. The outer skirt portion 271 is a portion where the carrier concentration monotonically decreases from a position where the carrier concentration shows the local maximum value P1 toward the upper surface 21. The outer skirt portion 272 is a portion where the carrier concentration monotonically decreases from a position where the carrier concentration shows the local maximum value P2 toward the lower surface 23.

Between the first carrier concentration peak 241 and the second carrier concentration peak 242, the outer skirt portion of one closer to the helium concentration peak 261 may be steeper than the outer skirt portion of another. In the example of FIG. 9, the outer skirt portion 272 is steeper than the outer skirt portion 271. A steep skirt portion means that an absolute value of a slope of the carrier concentration distribution is large. In another example, between the first carrier concentration peak 241 and the second carrier concentration peak 242, the outer skirt portion of one farther from the helium concentration peak 261 may be steeper than the outer skirt portion of another.

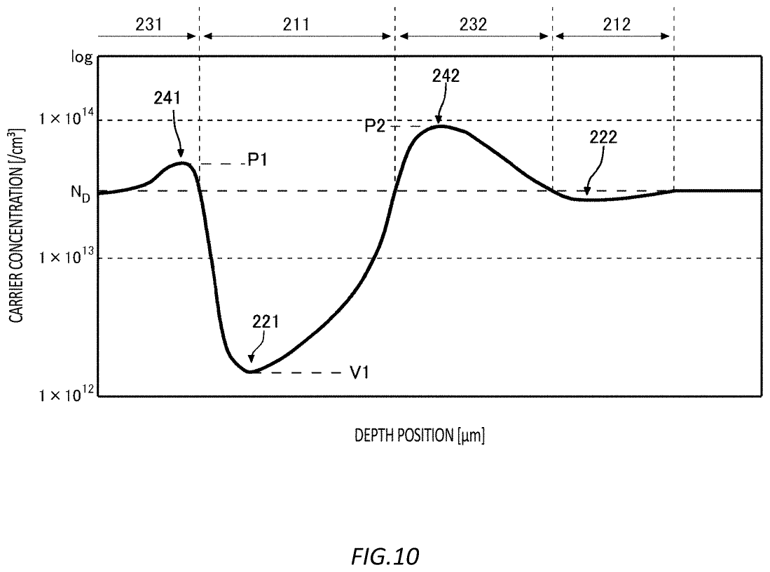

FIG. 10 is a diagram showing an example of the carrier concentration distribution in the first high concentration region 231, the first low concentration region 211, the second high concentration region 232, and the second low concentration region 212. The second low concentration region 212 may not be provided.

In the present example, similarly to the example shown in FIG. 8A, the hydrogen concentration peak 251 is provided on the lower surface 23 side with respect to the second high concentration region 232. Between the first carrier concentration peak 241 and the second carrier concentration peak 242, the concentration of one closer to the hydrogen concentration peak 251 may be higher than the concentration of another. In the present example, the second carrier concentration peak 242 is closer to the hydrogen concentration peak 251 than the first carrier concentration peak 241. By sufficiently increasing an amount of hydrogen diffusing from the hydrogen concentration peak 251 to the second carrier concentration peak 242, the local maximum value P2 in the second carrier concentration peak 242 can be made greater than the local maximum value P1 in the first carrier concentration peak 241. The amount of hydrogen diffusing from the hydrogen concentration peak 251 to the second carrier concentration peak 242 can be adjusted by using a dose amount of hydrogen ions implanted at the position of the hydrogen concentration peak 251, the distance L from the hydrogen concentration peak 251 to the second carrier concentration peak 242, annealing conditions of the semiconductor substrate 10, or the like. The concentration P2 may be 1.2 times or more, 1.5 times or more, or 2 times or more the concentration P1.

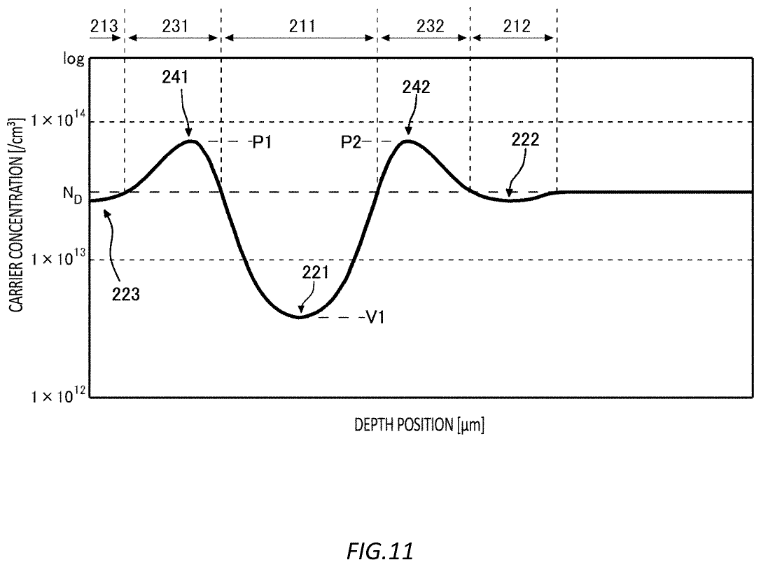

FIG. 11 is a diagram showing an example of the carrier concentration distribution in the first high concentration region 231, the first low concentration region 211, the second high concentration region 232, and the second low concentration region 212. The second low concentration region 212 may not be provided.

In the present example, similarly to the example shown in FIG. 8A, the hydrogen concentration peak 251 may be provided on the lower surface 23 side with respect to the second high concentration region 232. In the present example, a value obtained by dividing a higher concentration of the concentration P1 of the first carrier concentration peak 241 and the concentration P2 of the second carrier concentration peak 242 by a lower concentration thereof is 1.1 or less. That is, the concentration P1 and the concentration P2 are substantially the same. The concentration P1 may be higher than the concentration P2, and the concentration P2 may be higher than the concentration P1.

By making the hydrogen chemical concentration in the first high concentration region 231 and the hydrogen chemical concentration in the second high concentration region 232 substantially the same, the concentration P1 and the concentration P2 can be made substantially the same. The hydrogen chemical concentration of each region can be adjusted by using, for example, the dose amount of hydrogen ions implanted at the position of the hydrogen concentration peak 251, the distance L from the hydrogen concentration peak 251 to the second carrier concentration peak 242, the annealing conditions of the semiconductor substrate 10, or the like.

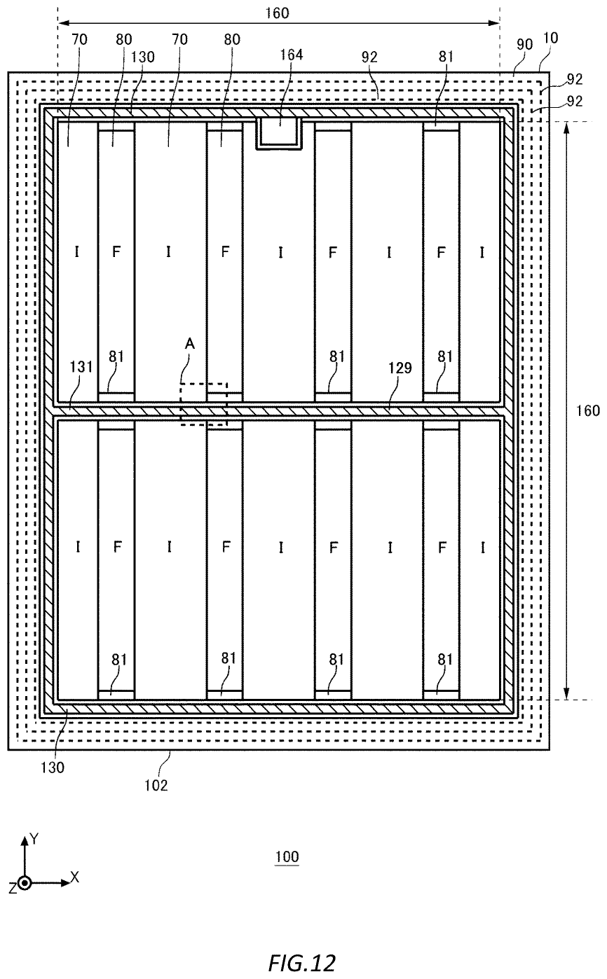

FIG. 12 is a diagram for explaining a more specific embodiment of the semiconductor device 100. FIG. 12 shows a position at which each member is projected on an upper surface of a semiconductor substrate 10. FIG. 12 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top view. As merely referred to as the top view in the present specification, it means that the semiconductor substrate 10 is viewed from the upper surface side. The semiconductor substrate 10 of the present example has two sets of end sides 162 opposite to each other in the top view. In FIG. 12, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 12. The active portion 160 may refer to a region that overlaps with the emitter electrode in the top view. In addition, a region sandwiched by the active portion 160 in the top view may also be included in the active portion 160.

The active portion 160 is provided with at least one of a transistor portion 70 including a transistor element such as an IGBT and a diode portion 80 including a diode element such as a freewheeling diode (FWD). In the example of FIG. 12, the transistor portion 70 and the diode portion 80 are alternately arranged along a predetermined array direction (the X axis direction in this example) on the upper surface of the semiconductor substrate 10. The semiconductor device 100 of the present example is a reverse-conducting IGBT (RC-IGBT).

In FIG. 12, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 12). Each of the transistor portions 70 and the diode portions 80 may have a longitudinal length in the extending direction. In other words, a length of the transistor portion 70 in the Y axis direction is greater than a width in the X axis direction. Similarly, a length of the diode portion 80 in the Y axis direction is greater than a width in the X axis direction. The extending directions of the transistor portion 70 and the diode portion 80, and a longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region which overlaps with the cathode region in the top view. At the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided at a lower surface of the extension region 81.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 12, the gate runner is hatched with diagonal lines.

The gate runner in the present example has an outer circumferential gate runner 130 and an active side gate runner 131. The outer circumferential gate runner 130 is arranged between the active portion 160 and the end side 162 of the semiconductor substrate 10 in the top view. The outer circumferential gate runner 130 in the present example encloses the active portion 160 in the top view. A region enclosed by the outer circumferential gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active side gate runner 131 is provided in the active portion 160. Providing the active side gate runner 131 in the active portion 160 can reduce a variation in a wiring length from the gate pad 164 for each region of the semiconductor substrate 10.

The outer circumferential gate runner 130 and the active side gate runner 131 are connected to the gate trench portion of the active portion 160. The outer circumferential gate runner 130 and the active side gate runner 131 are arranged above the semiconductor substrate 10. The outer circumferential gate runner 130 and the active side gate runner 131 may be a wiring formed of a semiconductor such as polysilicon doped with an impurity.

The active side gate runner 131 may be connected to the outer circumferential gate runner 130. The active side gate runner 131 in the present example is provided to extend in the X axis direction so as to cross the active portion 160 substantially at the center of the Y axis direction from one outer circumferential gate runner 130 to another outer circumferential gate runner 130 which sandwich the active portion 160. When the active portion 160 is divided by the active side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes an edge termination structure portion 90 between the active portion 160 and the end side 162 in the top view. The edge termination structure portion 90 in the present example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, or a RESURF which are annularly provided to enclose the active portion 160.

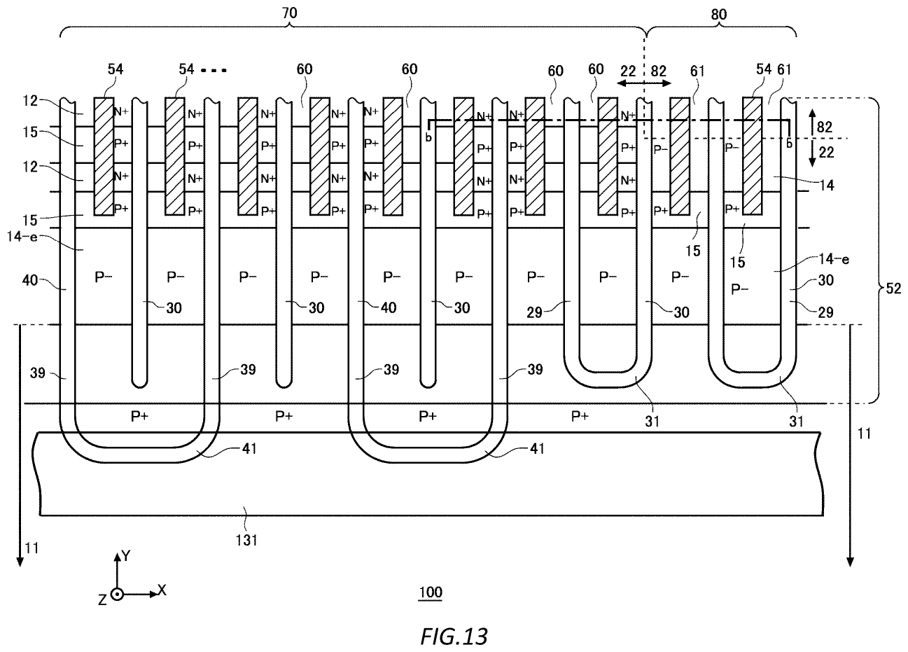

FIG. 13 shows an enlarged view of a region A in FIG. 12. The region A is a region including a transistor portion 70, a diode portion 80, and the active side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portions 30 is an example of the trench portion. In addition, the semiconductor device 100 in the present example includes an emitter electrode 52 and the active side gate runner 131 which are provided above the upper surface of the semiconductor substrate 10. The emitter electrode 52 and the active side gate runner 131 are provided to be separate from each other.

An interlayer dielectric film is provided between the emitter electrode 52 and the active side gate runner 131, and the upper surface of the semiconductor substrate 10; however, the interlayer dielectric film is omitted in FIG. 13. In the interlayer dielectric film in the present example, a contact hole 54 is provided to pass through the interlayer dielectric film. In FIG. 13, each contact hole 54 is hatched with diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and a gate conductive portion, and may be controlled to be at a potential different from a potential of the emitter electrode 52 and a potential of the gate conductive portion.

The active side gate runner 131 is connected to the gate trench portion 40 through the contact hole provided in the interlayer dielectric film. The active side gate runner 131 may be connected to a gate conductive portion of the gate trench portion 40 at an edge portion 41 of the gate trench portion 40 in the Y axis direction. The active side gate runner 131 is not connected to the dummy conductive portion in the dummy trench portion 30.

The emitter electrode 52 is formed of a material containing metal. FIG. 13 shows a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided to overlap with the active side gate runner 131. The well region 11 is provided to extend with a predetermined width even in a range that does not overlap with the active side gate runner 131. The well region 11 in the present example is provided to be spaced apart from an end of the contact hole 54 in the Y axis direction toward the active side gate runner 131. The well region 11 is a region of a second conductivity type having a higher doping concentration than that of the base region 14. The base region 14 in the present example is of the P− type, and the well region 11 is of the P+ type.

Each of the transistor portion 70 and the diode portion 80 has a plurality of trench portions arrayed in an array direction. In the transistor portion 70 in the present example, one or more gate trench portions 40 and one or more dummy trench portions 30 are alternately provided along the array direction. In the diode portion 80 in the present example, a plurality of dummy trench portions 30 are provided along the array direction. In the diode portion 80 in the present example, the gate trench portion 40 is not provided.

The gate trench portion 40 in the present example may have two linear portions 39 extending along the extending direction perpendicular to the array direction (parts of a trench which are linear along the extending direction), and the edge portion 41 connecting the two linear portions 39. The extending direction in FIG. 13 is the Y axis direction.

At least a part of the edge portion 41 is preferably provided in a curved shape in the top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or the plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 13 includes both of the linear dummy trench portion 30 having no edge portion 31, and the dummy trench portion 30 having the edge portion 31.

A diffusion depth of the well region 11 may be deeper than depths of the gate trench portion 40 and the dummy trench portion 30. The end portions in the Y axis direction of the gate trench portion 40 and the dummy trench portion 30 are provided in the well region 11 in the top view. In other words, at the end portion of each trench portion in the Y axis direction, a bottom portion of each trench portion in the depth direction is covered with the well region 11. With this configuration, the electric field strength at the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extending direction (the Y axis direction) along the trench, at the upper surface of the semiconductor substrate 10. In the present example, a mesa portion 60 is provided in the transistor portion 70, and a mesa portion 61 is provided in the diode portion 80. As merely referred to as the mesa portion in the present specification, it indicates each of the mesa portion 60 and the mesa portion 61.

Each mesa portion is provided with the base region 14. In the mesa portion, a region arranged to be closest to the active side gate runner 131, in the base region 14 exposed to the upper surface of the semiconductor substrate 10, is set as a base region 14-e. While FIG. 13 shows the base region 14-e arranged at one end portion of each mesa portion in the extending direction, the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is of the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact regions 15 and the emitter regions 12 of the mesa portion 60 are alternately arranged along the extending direction of the trench portion (the Y axis direction).

In another example, the contact region 15 and the emitter region 12 of the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in the present example is provided above each region of the contact region 15, the base region 14, and the emitter region 12. The contact hole 54 is not provided in regions corresponding to the base region 14-e and the well region 11. The contact hole 54 may be arranged at a center of the mesa portion 60 in the array direction (the X axis direction).

In the diode portion 80, a cathode region 82 of the N+ type is provided in a region adjacent to the lower surface of the semiconductor substrate 10. At the lower surface of the semiconductor substrate 10, the collector region 22 of the P+ type may be provided in a region where the cathode region 82 is not provided. The cathode region 82 and the collector region 22 are provided between a lower surface 23 of the semiconductor substrate 10 and a buffer region 20. In FIG. 13, a boundary between the cathode region 82 and the collector region 22 is indicated by a dotted line.

The cathode region 82 is arranged to be spaced apart from the well region 11 in the Y axis direction. With this configuration, the distance between a region of the P type (the well region 11) having a relatively high doping concentration and formed up to the deep position, and the cathode region 82 is ensured, so that a breakdown voltage can be improved. An end portion of the cathode region 82 in the Y axis direction in the present example is arranged to be spaced apart from the well region 11 farther than an end portion of the contact hole 54 in the Y axis direction. In another example, the end portion of the cathode region 82 in the Y axis direction may be arranged between the well region 11 and the contact hole 54.

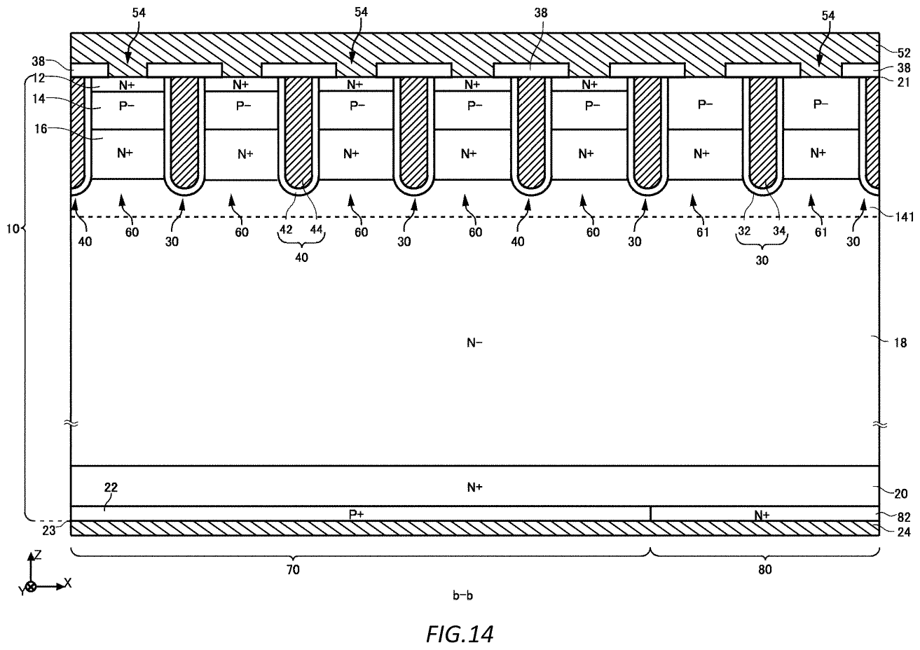

FIG. 14 is a view showing an example of a cross section e-e in FIG. 13. The cross section e-e is an XZ plane passing through the emitter region 12 and the cathode region 82. The semiconductor device 100 in the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with the contact hole 54 described with reference to FIG. 13.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided at the lower surface 23 of the semiconductor substrate 10. The emitter electrode 52 and the collector electrode 24 are formed of a metal material such as aluminum. In the present specification, a direction (the Z axis direction) in which the emitter electrode 52 is connected to the collector electrode 24 is referred to as the depth direction.

The semiconductor substrate 10 includes a drift region 18 of the N type or the N− type. The drift region 18 is provided in each of the transistor portion 70 and the diode portion 80.

In the mesa portion 60 of the transistor portion 70, the emitter region 12 of the N+ type and the base region 14 of the P− type are provided in order from the upper surface 21 side of the semiconductor substrate 10. The base region 14 is provided between the drift region 18 and the upper surface 21. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of the present example is provided in contact with the emitter region 12. The base region 14 may be in contact with the trench portions on both sides of the mesa portion 60.

The accumulation region 16 is provided between the drift region 18 and the base region 14. The accumulation region 16 is an N+ type region with a higher doping concentration than the drift region 18. That is, the accumulation region 16 has a donor concentration higher than that of the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover the entire lower surface of the base region 14 in each mesa portion 60.

The mesa portion 61 of the diode portion 80 is provided with the base region 14 of the P− type in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. The buffer region 20 of the present example is provided between the drift region 18 and the lower surface 23 of the semiconductor substrate 10. The doping concentration of the buffer region 20 is higher than the doping concentration of the drift region 18. The buffer region 20 may have a concentration peak having a doping concentration higher than that of the drift region 18. The doping concentration of the concentration peak refers to a doping concentration at a local maximum of the concentration peak. In addition, as the doping concentration of the drift region 18, an average value of the doping concentration in a region where the doping concentration distribution is substantially constant may be used.

The buffer region 20 may have two or more concentration peaks in the depth direction (the Z axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stopper layer which prevents a depletion layer expanding from a lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the example described above. The collector region 22 and the cathode region 82 are exposed to the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. A boundary between the diode portion 80 and the transistor portion 70 in the X axis direction, in the present example, is a boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor at the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It is noted that the bottom portion of the dummy trench portion 30 and the gate trench portion 40 may be formed in a curved-surface shape (a curved-line shape in the cross section) convexly downward.

Below the gate trench portion 40 and the dummy trench portion 30, a lifetime adjustment region 141 where the carrier lifetime shows a local minimum value in the depth direction of the semiconductor substrate 10 is provided. A part of the lifetime adjustment region 141 may be arranged above lower ends of the gate trench portion 40 and the dummy trench portion 30.

The first high concentration region 231 and the accumulation region 16 described with reference to FIGS. 1 to 11 may overlap with each other. The entire first high concentration region 231 may function as the accumulation region 16. In addition, the first low concentration region 211 and the lifetime adjustment region 141 described with reference to FIGS. 1 to 11 may overlap with each other. The entire first low concentration region 211 may function as the lifetime adjustment region 141. According to the present example, the accumulation region 16 and the lifetime adjustment region 141 can be formed by a simple manufacturing step.

The hydrogen concentration peak 251 described in FIGS. 1 to 11 may be provided in the buffer region 20. The buffer region 20 overlaps with the hydrogen concentration peak 251 and has a carrier concentration peak. The carrier concentration peak is a peak of the hydrogen-related donor. According to the present example, the accumulation region 16, the lifetime adjustment region 141, and the buffer region 20 can be formed by a simple manufacturing step.

The second high concentration region 232 described in FIGS. 1 to 11 may overlap with the drift region 18. In this case, at least a part of the drift region 18 can be increased in concentration by a simple manufacturing step. The second low concentration region 212 described in FIGS. 1 to 11 may overlap with the drift region.

While the present invention has been described by way of the embodiments, the technical scope of the present invention is not limited to the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” for convenience in the claims, embodiments, or diagrams, it does not necessarily mean that the process must be performed in this order.

The present specification and the drawings also disclose inventions according to following items.

### Item 1

A semiconductor device which is provided in a semiconductor substrate having a first principal surface and a second principal surface and containing a bulk dopant, the semiconductor device including:
in the semiconductor substrate, a first low concentration region of a first conductivity type which has a carrier concentration lower than a bulk concentration that is a concentration of the bulk dopant; and
a first high concentration region of the first conductivity type which has a first carrier concentration peak at a position in contact with the first low concentration region on a side of the first principal surface and has a carrier concentration higher than the bulk concentration, in which
a hydrogen concentration peak is not provided at a position overlapping with the first carrier concentration peak.

### Item 2

The semiconductor device according to item 1, in which
the first high concentration region includes a hydrogen-related donor.

### Item 3

The semiconductor device according to item 2, in which
the first carrier concentration peak is a concentration peak of a hydrogen-related donor.

### Item 4

The semiconductor device according to item 1, in which
the first low concentration region has a helium concentration peak in a depth direction of the semiconductor substrate.

### Item 5

The semiconductor device according to item 4, in which
a width of the helium concentration peak in the depth direction is smaller than a width of the first low concentration region in the depth direction.

### Item 6

The semiconductor device according to any one of items 1 to 5, further including
a second high concentration region of the first conductivity type which has a second carrier concentration peak at a position in contact with the first low concentration region on a side of the second principal surface and has a carrier concentration higher than the bulk concentration.

### Item 7

The semiconductor device according to item 6, in which
the hydrogen concentration peak is provided on the side of the second principal surface with respect to the second carrier concentration peak.

### Item 8

The semiconductor device according to item 7, in which
a hydrogen concentration of the hydrogen concentration peak is 1×10¹⁶/cm³ or more.

### Item 9

The semiconductor device according to item 6, in which
a constant lifetime portion in which carrier lifetime is constant in a depth direction of the semiconductor substrate is provided between the second carrier concentration peak and the hydrogen concentration peak.

What is claimed is:

1. A semiconductor device which is provided in a semiconductor substrate having a first principal surface and a second principal surface and containing a bulk dopant, the semiconductor device comprising:
in the semiconductor substrate, a first low concentration region of a first conductivity type which has a carrier concentration lower than a bulk concentration that is a concentration of the bulk dopant; and
a first high concentration region of the first conductivity type which has a first carrier concentration peak at a position in contact with the first low concentration region on a side of the first principal surface and has a carrier concentration higher than the bulk concentration, wherein
a hydrogen concentration peak is not provided at a position overlapping with the first carrier concentration peak.

2. The semiconductor device according to claim 1, wherein
the first high concentration region includes a hydrogen-related donor.

3. The semiconductor device according to claim 2, wherein
the first carrier concentration peak is a concentration peak of a hydrogen-related donor.

4. The semiconductor device according to claim 1, wherein
the first low concentration region has a helium concentration peak in a depth direction of the semiconductor substrate.

5. The semiconductor device according to claim 4, wherein
a width of the helium concentration peak in the depth direction is smaller than a width of the first low concentration region in the depth direction.

6. The semiconductor device according to claim 1, further comprising
a second high concentration region of the first conductivity type which has a second carrier concentration peak at a position in contact with the first low concentration region on a side of the second principal surface and has a carrier concentration higher than the bulk concentration.

7. The semiconductor device according to claim 6, wherein
the hydrogen concentration peak is not provided at a position overlapping with the second carrier concentration peak.

8. The semiconductor device according to claim 7, wherein
the second carrier concentration peak is a concentration peak of a hydrogen-related donor.

9. The semiconductor device according to claim 6, wherein
between the first carrier concentration peak and the second carrier concentration peak, one closer to the hydrogen concentration peak has a concentration higher than that of another.

10. The semiconductor device according to claim 6, wherein
between the first carrier concentration peak and the second carrier concentration peak, one closer to any one of the first principal surface or the second principal surface has a concentration higher than that of another.

11. The semiconductor device according to claim 6, wherein
a value obtained by dividing a higher concentration of a concentration of the first carrier concentration peak and a concentration of the second carrier concentration peak by a lower concentration thereof is 1.1 or less.

12. The semiconductor device according to claim 1, further comprising
a second high concentration region of the first conductivity type which has a second carrier concentration peak at a position in contact with the first low concentration region on a side of the second principal surface and has a carrier concentration higher than the bulk concentration, wherein
the first low concentration region has a helium concentration peak in a depth direction of the semiconductor substrate, and
between a concentration of the first carrier concentration peak and a concentration of the second carrier concentration peak, one closer to the helium concentration peak is lower than another.

13. The semiconductor device according to claim 1, further comprising
a second high concentration region of the first conductivity type which has a second carrier concentration peak at a position in contact with the first low concentration region on a side of the second principal surface and has a carrier concentration higher than the bulk concentration, wherein
the first low concentration region has a helium concentration peak in a depth direction of the semiconductor substrate,
the first carrier concentration peak and the second carrier concentration peak each have an outer skirt portion on an opposite side to the helium concentration peak, and
between the first carrier concentration peak and the second carrier concentration peak, the outer skirt portion of one closer to the helium concentration peak is steeper than the outer skirt portion of another.

14. The semiconductor device according to claim 6, further comprising
a second low concentration region which has a valley portion of a carrier concentration at a position in contact with the second high concentration region on the side of the second principal surface.

15. The semiconductor device according to claim 6, wherein
the hydrogen concentration peak is provided on the side of the second principal surface with respect to the second carrier concentration peak.

16. The semiconductor device according to claim 15, wherein
a distance in a depth direction of the semiconductor substrate between the hydrogen concentration peak and the second carrier concentration peak is equal to or more than ¼ of a thickness in the depth direction of the semiconductor substrate.

17. The semiconductor device according to claim 6, wherein
a constant lifetime portion in which carrier lifetime is constant in a depth direction of the semiconductor substrate is provided between the second carrier concentration peak and the hydrogen concentration peak, and
a flat hydrogen concentration portion in which a hydrogen concentration is flat in the depth direction of the semiconductor substrate is provided between the first carrier concentration peak and the hydrogen concentration peak.

18. The semiconductor device according to claim 1, comprising:
a drift region of the first conductivity type which is provided in the semiconductor substrate;
a base region of a second conductivity type which is provided between the drift region and the first principal surface;
a trench portion which is provided from the first principal surface to a position below the base region;
an accumulation region which is provided between the drift region and the base region and has a carrier concentration higher than that of the drift region; and
a lifetime adjustment region which is provided below the trench portion and has a carrier lifetime showing a local minimum value in a depth direction of the semiconductor substrate, wherein
the first high concentration region and the accumulation region overlap with each other, and
the first low concentration region and the lifetime adjustment region overlap with each other.

19. The semiconductor device according to claim 18, further comprising
a buffer region of the first conductivity type which is provided between the drift region and the second principal surface and has a carrier concentration higher than that of the drift region, wherein
the hydrogen concentration peak is provided in the buffer region.

20. The semiconductor device according to claim 6, comprising:
a drift region of the first conductivity type which is provided in the semiconductor substrate;
a base region of a second conductivity type which is provided between the drift region and the first principal surface;
a trench portion which is provided from the first principal surface to a position below the base region; and
a lifetime adjustment region which is provided below the trench portion and has a carrier lifetime showing a local minimum value in a depth direction of the semiconductor substrate, wherein
the first low concentration region and the lifetime adjustment region overlap with each other, and
the second high concentration region and the drift region overlap with each other.
